(19) United States
(12) Patent Application Publication
(10) Pub. No.: US 2007/0246788 A1
(43) Pub. Date: Oct. 25, 2007

(54) N-well barrier pixels for improved protection of dark reference columns and rows from blooming and crosstalk

(76) Inventors: Richard A. Mauritzson, Meridian, ID (US); Inna Patrick, Boise, ID (US)

Correspondence Address: DICKSTEIN SHAPIRO LLP, 1825 EYE STREET, NW, WASHINGTON, DC, 20006, US

(21) Appl. No.: 11/408,194

(22) Filed: Apr. 21, 2006

(51) Int. Cl. H01L 27/14; H01L 21/00

(52) U.S. Cl. 257/431; 438/57

(57) ABSTRACT

The barrier region for isolating one or more dark regions of the pixel array of an image sensor from the active array or from the peripheral circuitry includes N-well pixel isolation region. The N-well pixel isolation region includes at least one N-well implant or at least one N-well stripe. The N-well pixel isolation region is adjacent the pixel cells which comprise the dark region. The addition of the N-well in the barrier region improves the isolation properties of the barrier region by reducing or eliminating the neutral P− EPI region in the barrier pixel area below the N-well isolation region.

### FIELD OF THE INVENTION

The present invention relates to the field of semiconductor devices, particularly to improved isolation techniques for image sensors.

### BACKGROUND OF THE INVENTION

An image sensor generally includes an array of pixel cells arranged in rows and columns. Each pixel cell includes a photo-conversion device for converting light incident on the array into electrical signals. An image sensor also typically includes peripheral circuitry for controlling devices of the array and for converting the electrical signals into a digital image.

FIG. 1 illustrates a portion of a typical CMOS image sensor 100. Image sensor 100 includes an array 105 of pixel cells 110. The pixel cells 110 are arranged in columns and rows, a portion 145 of the array shows this arrangement with four pixel cells, two in each row and column. The array 105 includes pixel cells 110 in an active array region 115 and pixel cells 110 in a black region 120. The black region 120 is similar to the active array region 115, except that light is prevented from reaching the photo-conversion devices of the pixel cells 110 in the black region 120 by, for example, a metal layer, a black color filter array, or any opaque material. Signals from pixel cells 110 of the black region 120 can be used to determine the black level for the array 105, which is used to adjust the resulting image produced by the image sensor 100.

FIGS. 2A and 2B, respectively show a top down arrangement and electrical schematic diagram of an exemplary four transistor (4T) pixel cell 110. Pixel cell 110 functions by receiving photons of light and converting those photons into electrons. For this, each one of the pixel cells 110 includes a photosensor 205, or any type of photo-conversion device such as a photogate, photoconductor, or other photosensitive device. The photosensor 205 includes a photosensor charge accumulation region 210 and a p-type surface layer 215.

Each pixel cell 110 also includes a transfer transistor 220 for transferring charge from the photosensor charge accumulation region 210 to a floating diffusion region 225 and a reset transistor 230, for resetting the floating diffusion region 225 to a predetermined charge level Vaa-pix, prior to charge transfer. The pixel cell 110 also includes a source follower transistor 235 for receiving and amplifying a charge level from the floating diffusion region 225 and a row select transistor 240 for controlling the readout of the pixel cell 110 contents from the source follower transistor 235. As shown in FIG. 2A, the reset transistor 230, the source follower transistor 235 and the row select transistor 240 include source/drain regions 245, 250 and 255 respectively.

Several contacts 260, 265 and 270 provide electrical connections for the pixel cell 110. For example, as shown in FIG. 2A, a source/drain region 245 of the reset transistor 230 is electrically connected to an array voltage source terminal providing Vaa-pix through first contact 260; the gate of the source follower transistor 235 is connected to the floating diffusion region 225 through a second contact 265; and an output voltage Vout is output from the pixel cell 110 through a third contact 270.

Referring again to FIG. 1, after pixel cells 110 of array 105 generate charge in response to incident light, electrical signals indicating charge levels are read out and processed by circuitry 125 peripheral to array 105. Peripheral circuitry 125 typically includes row select and driver circuitry 130 and column or readout select circuitry 135 for activating particular rows and columns of the array 105; and other circuitry 140, which can include analog signal processing circuitry, analog-to-digital conversion circuitry, and digital logic processing circuitry as is known in the art. Peripheral circuitry 125 may be located adjacent to the array 105 as shown in FIG. 1.

Ideally, light received by each photosensor 205 travels directly from the source being imaged, through a pixel surface facing the light stimulus, and strikes the photosensor 205. In reality, however, light entering the optoelectronic converter is scattered by reflection and refraction by pixel structures. Consequently, an individual photosensor 205 can receive stray light, such as light that is intended for neighboring photosensors in the array. This stray light, referred to as optical “crosstalk,” reduces the quality and accuracy of the rendered image. The problems associated with optical crosstalk become increasingly more evident as imagers become smaller and array pixel densities increase.

Optical crosstalk is particularly problematic in color imagers, in which each pixel assumes a specialized light-detecting role. The photosensor in a typical pixel is sensitive to a wide spectrum of light energy. Consequently, the pixels of an array of pixels provide a light intensive signal. Color filters can be used to limit the wavelengths of the light that strike particular photosensors to provide a color image. In color imagers, color filter mosaic arrays (CFAs) are arranged in the light paths of respective photosensors to impart color-sensitivity to the imager. In most cases a three-color red-green-blue (RGB) pattern is used, such that each pixel cell is responsive to one of these colors, although other color patterns may also be used. The CFAs are arranged in a pattern, with the known Bayer pattern 145 (FIG. 1) being the predominate arrangement used. The result is an imager capable of rendering color images in the visible light spectrum.

Ideally, each photosensor will receive only those wavelengths of light intended for it to convert. In reality, however, optical crosstalk between the pixels allows light directed through one color filter to strike another pixel causing that pixel to register more light than is actually present in the image being viewed. In addition, CFA imperfections will allow additional crosstalk in the form of, for example, some blue and green light entering red pixels or red light entering blue and green pixels. These various types of crosstalk reduce the accuracy of the images produced.

In addition, in order to obtain a high quality image, it is important that the peripheral circuitry 125 not interfere with the pixel cells 110 of the array 105. During operation, the peripheral circuitry 125 generates charge carriers, e.g., electrons. If the peripheral circuitry 125 is adjacent to the array 105, electrons generated by the peripheral circuitry 125 can travel to and interfere with array pixel cells 110, especially those pixel cells 110 on the edges of the array 105 adjacent the peripheral circuitry 125. The interfering electrons are misinterpreted as a true pixel signal and image distortion can occur.

Another problem encountered in the conventional image sensor 100 is interference from the active array region 115 with the black region 120. When very bright light is incident on pixel cells 110 of the active array region 115 adjacent to the black region 120, blooming can occur and excess charge from these pixel cells 110 of the active array region 115 can travel to and interfere with pixel cells 110 in the adjacent black region 120. This can cause inaccurate black levels and distortion of the resultant image.

Blooming and electron diffusion is also possible both through P− epitaxial (Epi) and P+ substrates and may be dependent on the Epi thickness, the substrate doping and the minority carrier lifetimes in silicon. While barrier pixels have been used to reduce the diffusion component through P− Epi, barrier pixels still allow blooming and diffusion through a substrate when insufficient space is allocated to the barrier pixels. As Epi thickness is increased, the effects of blooming through Epi also increase. A number of barrier pixels must be allocated between the array and the dark pixels to reduce blooming and electron diffusion. The number of pixel cells allocated is dependent on the diffusion length (the length the electron may travel) in the P− Epi and/or P+ substrate.

Accordingly, it would be advantageous to have an improved image sensor where the interference from the active region experienced by the black region is reduced, the interference from the peripheral circuitry on the black region is reduced, and/or the image sensor is improved by requiring a reduced number of pixels to be devoted to barrier areas.

### BRIEF DESCRIPTION OF THE DRAWINGS

Exemplary embodiments of the invention provide an improved barrier region for isolating devices of an image sensor. The improved barrier region includes enhancing the isolation properties of barrier pixels by combining the barrier pixels with one or more N-well stripes or by incorporating one or more N-well implants into the photosensor implants of the barrier pixels.

The foregoing and other advantages and features of the invention will become more apparent from the detailed description of exemplary embodiments provided below with reference to the accompanying drawings in which:

FIG. 1 is a top plan view block diagram of a conventional image sensor;

FIG. 2A is a top plan view of a conventional CMOS pixel cell;

FIG. 2B is a schematic diagram of the pixel cell of FIG. 2A;

FIGS. 3A, and 3B are top plan view block diagrams of image sensors according to exemplary embodiments of the invention;

FIG. 3C is a state of the art barrier pixel including arrows symbolizing electron diffusion in neutral P− EPI;

FIG. 3D is a N-well barrier pixel including arrows symbolizing electron diffusion in neutral P− EPI;

FIGS. 4A-4F depict examples of the formation of the N-well barrier region of FIG. 3A at intermediate stages of processing;

FIG. 5 depicts an example of N-well barrier region below pixel P_{D};

FIGS. 6A, and 6B depict examples of ways to bias N-well region; and

FIG. 7 is a block diagram of a processor system according to an exemplary embodiment of the invention.

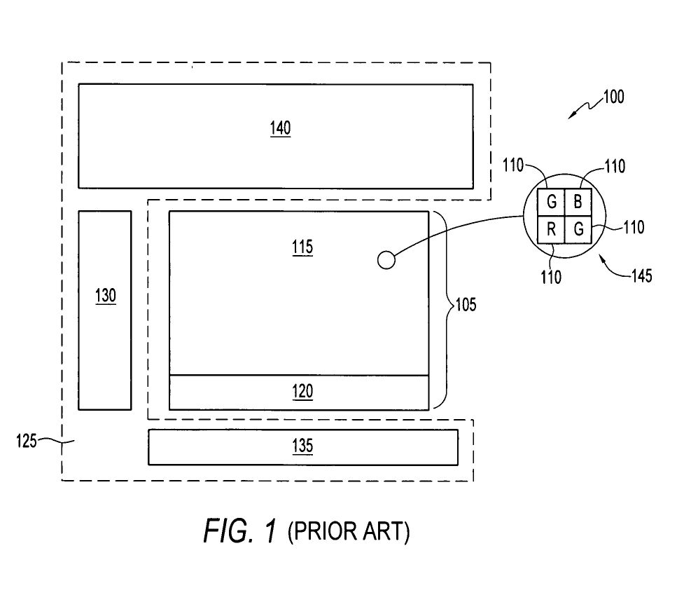

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe like elements throughout the several views. These embodiments are described in sufficient detail to enable those skilled in the art to practice the invention, and it is to be understood that other embodiments may be utilized, and that structural, logical and electrical changes may be made without departing from the spirit and scope of the present invention.

The term “substrate” is to be understood as including silicon, silicon-on-insulator (SOI), or silicon-on-sapphire (SOS) technology, doped and undoped semiconductors, epitaxial layers of silicon supported by a base semiconductor or other foundation, and other semiconductor structures. Furthermore, when reference is made to a “substrate” in the following description, previous process steps may have been utilized to form regions or junctions in the base semiconductor structure or foundation. In addition, the semiconductor need not be silicon-based, but could be based on silicon-germanium, germanium, gallium-arsenide, or other semiconductor material.

The term “pixel” or “pixel cell” refers to a picture element unit cell containing a photo-conversion device for converting electromagnetic radiation to an electrical signal. Typically, the fabrication of all pixel cells in an image sensor will proceed concurrently in a similar fashion.

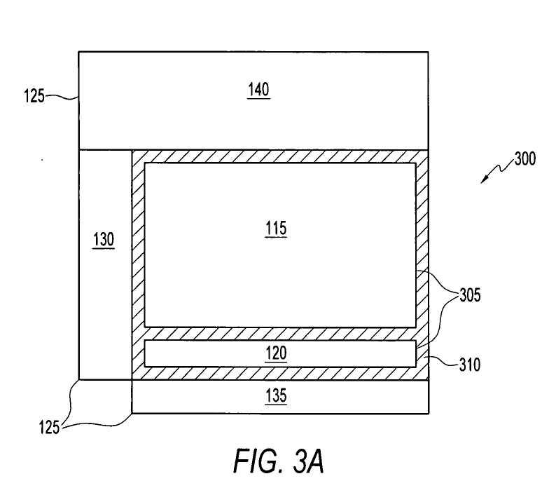

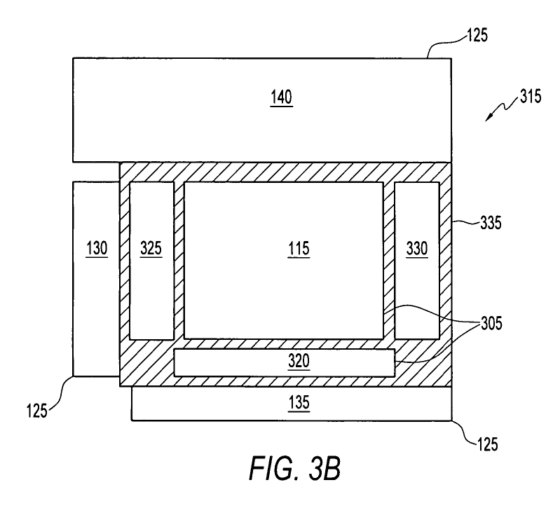

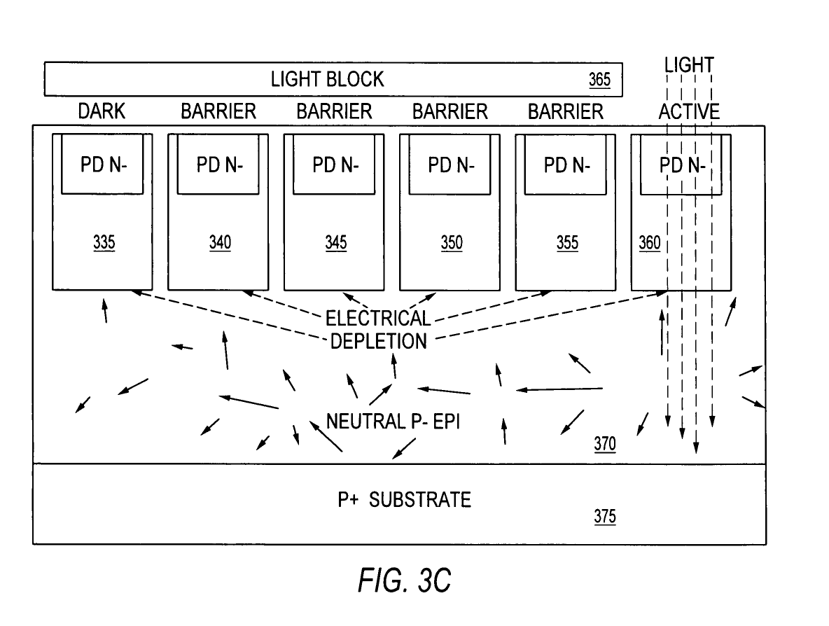

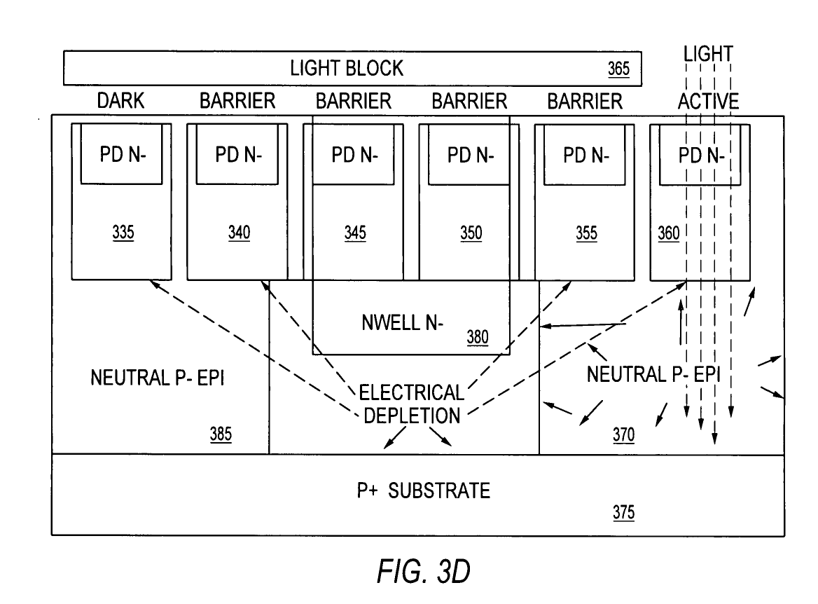

FIG. 3A depicts a top down view of a portion of an image sensor 300 according to an exemplary embodiment of the invention. Image sensor 300 includes a pixel array 305 including an active array region 115 and black region 120. There is also peripheral circuitry 125 adjacent to the array 305. The peripheral circuitry 125 can include row select circuitry 130 and column select or readout circuitry 135 for activating the array 105; and other circuitry 140, which can include analog signal processing circuitry, analog-to-digital conversion circuitry, and digital logic processing circuitry. The configuration of the image sensor 300 is exemplary only. Accordingly, the image sensor 300 need not include peripheral circuitry 125 adjacent to the array 305 and/or array 305 need not include black region 120. FIG. 3A also includes N-well barrier pixel 310, formed by the addition of N-well implants within the barrier area. In FIG. 3A N-well barrier pixels 310 may surround the array 305 as a whole including the active array region 115 and the black region 120. N-well barrier pixels of other sizes or surrounding other components are within the scope of the present invention as well. N-well barrier pixels may successfully be used when positioned in the space between pixel cells 110 and peripheral circuitry 125 or other sources of crosstalk, blooming or other sources of interference. N-well barrier pixels may be continuous as shown in FIG. 3A or may include a series of individual N-well barrier pixels positioned where desired to reduce interference between the active array region 115 and the black region 120. In an exemplary embodiment the N-well barrier pixels are positioned in the barrier region located between the active array region 115 and the black region 120.

FIG. 3B depicts a top down view of an image sensor 315 according to another exemplary embodiment of the invention. The image sensor 315 is similar to image sensor 300, except that image sensor 315 includes dark reference rows 320 and dark reference columns 325 and 330 whereas image sensor 300 only included black pixels located in black area 120. Like black region 120 of FIG. 3A, the dark reference rows 320 and the dark reference columns 325 and 330 include pixel cells 110 where light is prevented from reaching the photo-conversion devices of the pixel cells 110. The dark reference rows 320 and the dark reference columns 325 and 330 operate in the same manner as black region 120. Therefore, without isolation, from, for example, barrier pixels, the dark reference rows 320 and the dark reference columns 325 and 330 may experience interference from pixel cells of active array region 115 or peripheral circuitry 125. In FIG. 3B N-well barrier area 335, formed by the addition of N-well implants within the barrier pixels are located in the space between the active array region 115 and the dark reference rows 320, and the dark reference columns 325 and 330. N-well barrier pixel areas of other sizes or surrounding other components are within the scope of the present invention.

FIG. 3C is a state of the art barrier pixel including solid arrows symbolizing electron diffusion in neutral P− EPI. FIG. 3C includes a dark pixel 335 which is located in a black region such as black region 120 of FIG. 3A or dark reference columns 325 and 330 and dark reference rows 320 of FIG. 3B. Also included in FIG. 3 C are four barrier pixels 340, 345, 350 and 355 located in a barrier region, and an active pixel 360 located in the active array. Additionally, a light block 365 is included which provides a barrier between light sources and the dark pixel 335 and barrier pixels 340, 345, 350 and 355. Light enters active pixel 360 which is located in the active array and is diffused through the Neutral P− EPI layer 370. Despite the presence of the barrier pixels 340, 345, 350 and 355, dark pixel 335 receives diffused electrons from the light entering the active pixel 360 located in the active array. Also shown in FIG. 3C is the P+ Substrate 375.

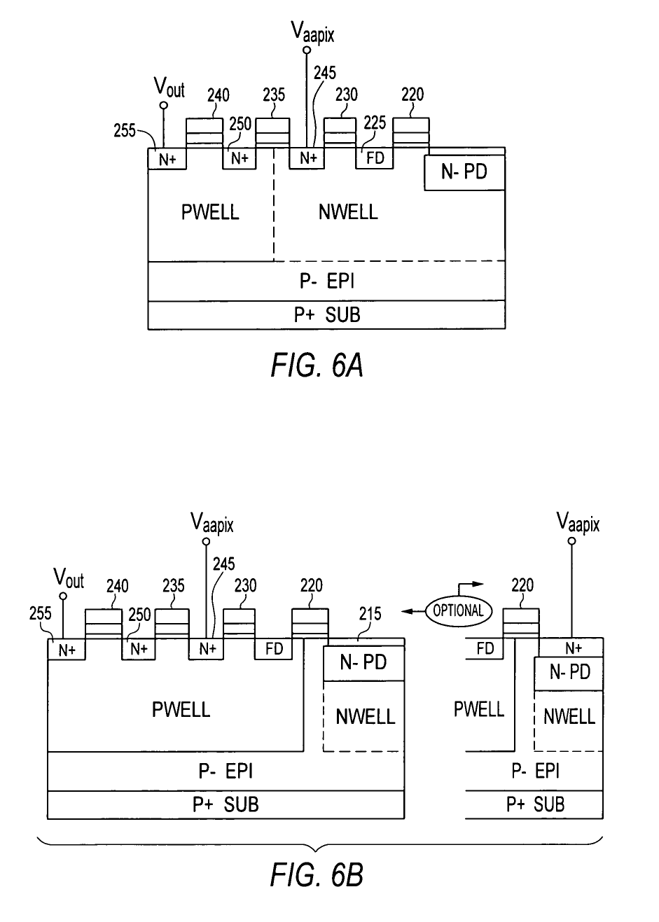

FIG. 3D is a N-well barrier pixel including solid arrows symbolizing electron diffusion in neutral P− EPI. As shown, an N-well N-region 380 is located beneath barrier pixels 345 and 350. In this case as light enters active pixel 360, electrons are diffused through the Neutral P− EPI region 370. The N-well N-region 380 located beneath barrier pixels 345 and 350 absorbs the diffused electrons such that few if any diffused electrons reach Neutral P− EPI region 385. The N-well N-region ensures that the light encountered by dark pixel 335 is minimized. The addition of the N-well in the barrier region improves the isolation properties of the barrier region by reducing or eliminating the neutral P− EPI region in the barrier pixel area below the N-well isolation region 380. The N-well region under the pixel must be biased with a positive voltage to be effective. This voltage potential can be supplied by existing biased regions within the pixel or additional contacts. For example, and without limitation, the N-well region, if implanted only below the PD 205 can be biased by the PD potential or external contact to the PD region. Alternatively, if the N-well is implanted under the entire pixel cell 110, then the N-well region can be biased through the vaa-pix contact 260 and source/drain region 245. FIG. 6A illustrates a N-well stripe being biased to vaa-pix, which may be any positive potential. FIG. 6B illustrates N-well only under the photodiode which may be biased to the PD potential or tied directly to vaa-pix.

Illustratively, image sensors 300, and 315 of FIGS. 3A, and 3B respectively, are CMOS image sensors and array 305 includes CMOS pixel cells 110. It should be noted, however, that embodiments of the invention include other solid state imager arrays, including those used in CCD image sensors and similar devices. In such a case, array 305 would instead include pixel cells and peripheral circuitry suitable for the CCD image sensor or similar device.

It should be further noted that the configuration of pixel cell 110 is only exemplary and that various changes may be made as are known in the art and pixel cell 110 may have other configurations. Although the invention is described in connection with a four-transistor (4T) CMOS pixel cell 110, the invention may also be incorporated into other CMOS pixel circuits having different numbers of transistors. Without limitation, such a circuit may include a three-transistor (3T) pixel cell, a five-transistor (5T) pixel cell, a six-transistor (6T) pixel cell, and a seven-transistor pixel cell (7T). A 3T cell may omit the transfer transistor or row select transistor. The 5T, 6T, and 7T pixel cells differ from the 4T pixel cell by the addition of one, two, or three transistors, respectively, such as a shutter transistor, an anti-blooming transistor, a dual conversion gain transistor, etc.

The isolation properties of the N-well barrier areas 310 of FIGS. 3A and 335 of FIG. 3B are enhanced by the addition of one or more N-well implants in the photosensor implants of the barrier pixels. The depletion depth of N-well pixel implant regions reach deeper than the typical photosensor depletion reaches in the Epi silicon. Depleting the whole Epi thickness with the N-well barrier provides the best crosstalk and blooming protection for the dark reference pixels such as black region 13 (FIG. 3A), dark reference rows 320 (FIG. 3B) and dark reference columns 325 and 330 (FIG. 3B). The increased depth of the N-well stripes or N-well implants of the N-well barrier pixels improve the ability of the barrier pixel to collect “stray” electrons when biased by extending their depletion depth to the CMOS Imager P+ Substrate depth. The increased isolation capabilities of the N-well barrier pixels result in less pixel cells 110 of array 105 being dedicated to serve as a barriers. In general the dose concentrations for N-well N-region is 1×10¹⁶ to 1×10¹⁸/cm3 with a preferable concentration being 5×10¹⁶ to 5×10¹⁷/cm3. The general range for the depth of the N-well N-region is 0.5 to 3 micrometers with a preferred depth being 1 to 2 micrometers. In general the dose concentrations for Photodiode N-region is 1×10¹⁶ to 1×10¹⁸/cm3 with a preferable concentration being 5×10¹⁶ to 5×10¹⁷/cm3. The general range for the depth of the Photodiode N− region is 0.25 to 1.5 micrometers with a preferred depth being 0.4 to 1.0 micrometers.

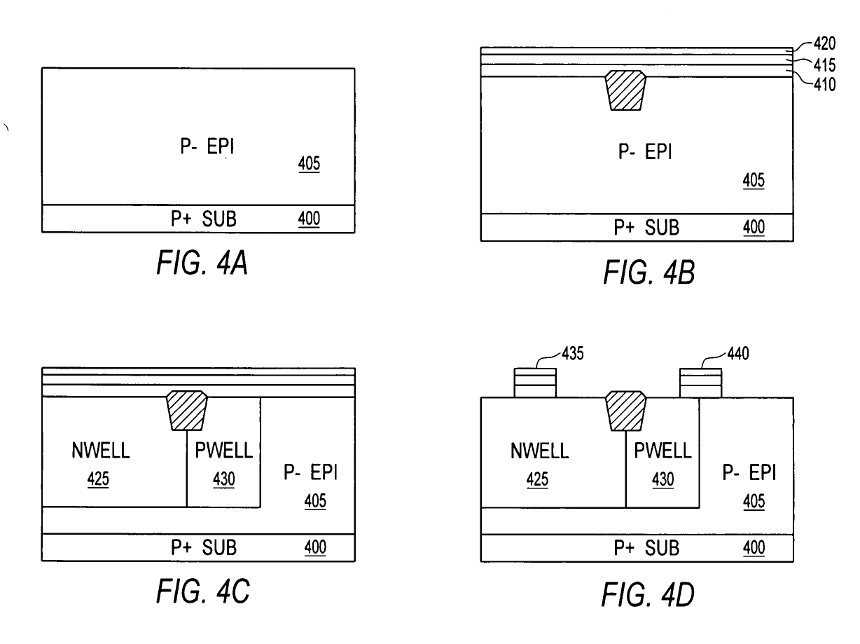

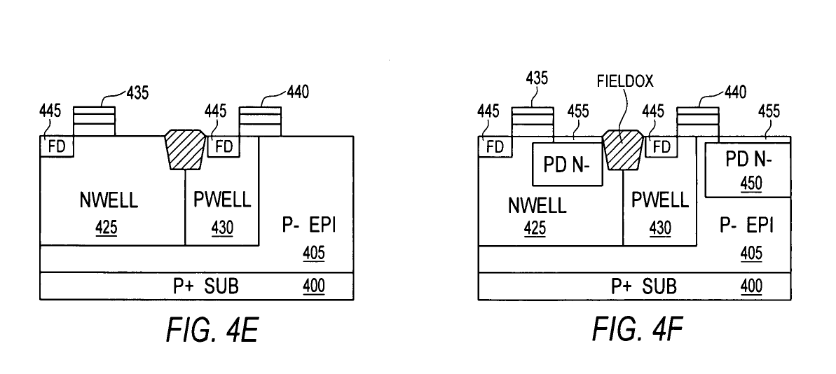

FIGS. 4A-4F depict fabrication steps for an N-well barrier region 310 according to one exemplary embodiment of the invention. No particular order is required for any of the actions described herein, except for those logically requiring the results of prior actions. Accordingly, while the actions below are described as being performed in a general order, the order is exemplary only and can be altered.

Referring to FIGS. 4A-4F, the N-well barrier region 310 can be formed simultaneously with the pixel cells of array 305 (FIGS. 3A and 3B). Also, the formation of a plurality of N-well barrier regions 310 can proceed simultaneously and in a similar manner as described below in connection with FIGS. 4A-4F.

As shown in FIGS. 4A-4F, N-well barrier region 425 is formed above the P+ substrate 400 and at a surface of a P− EPI layer 405. As noted above, previous process steps may have been utilized to form regions (not shown) or junctions (not shown) in the substrate 400 or the P− EPI layer 405. For example, isolation regions, e.g., shallow trench isolation regions can be formed by known techniques in substrate 400 or the EPI layer 405 prior to the formation of N-well barrier region 425. FIG. 4A shows a starting P+ substrate 400 and a P− EPI layer 405.

FIG. 4B shows the addition of a first insulating layer 410, a conductive layer 415, and a second insulating layer 420. The first insulating layer 410 of, for example, silicon oxide is grown or deposited on the P− EPI layer 405. The first insulating layer 410 serves as the gate oxide layer for the subsequently formed transfer and reset transistors 220, 230. Next, the layer of conductive material 415 is deposited over the first insulating layer 410. The conductive layer 415 serves as the gate electrode for the subsequently formed transfer and reset transistors 220, 230. The conductive layer 415 can be a layer of polysilicon, which can be doped n-type. The second insulating layer 420 is deposited over the conducting layer 415. The second insulating layer 420 can be formed of, for example, an oxide (SiO2), a nitride (silicon nitride), an oxynitride (silicon oxynitride), ON (oxide-nitride), NO (nitride-oxide), or ONO (oxide-nitride-oxide). The layers 410, 415, 420 can be blanket formed by conventional deposition methods, such as chemical vapor deposition (CVD) or plasma enhanced chemical vapor deposition (PECVD), among others.

As shown in FIG. 4C, the N-well barrier region 425 is formed at a surface of a P− EPI layer 405, which is illustratively a p-type region. Also, as shown in FIG. 4C, a P-well region may also be formed at a surface of P− EPI layer 405. The N-well implant 425 is formed in the EPI layer 405 from a point below the first insulating layer 410 and extending to between the expected positions of the gate stack 435. The N-well implant 425 may be formed by known methods such as, for example and without limitation, implanting relatively fast-diffusing N type atoms. The illustrated pixels are barrier pixels formed between the active array pixels and the black pixels.

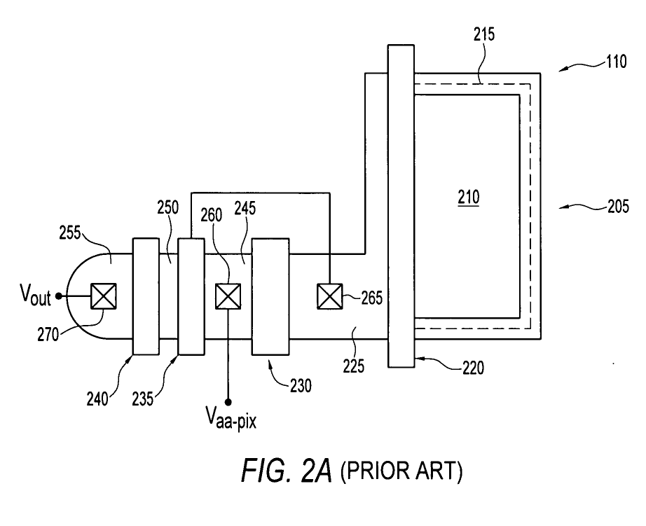

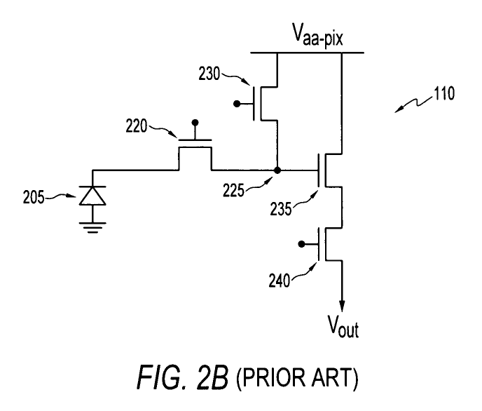

As shown in FIG. 4D, the layers 410, 415, 420 are then patterned and etched to form the transfer and reset transistor 220, 230 (FIGS. 2A and 2B) multilayer gate stacks 435-440 shown in FIG. 4D. The invention is not limited to the structure of the gate stacks 435-440 described above. Additional layers may be added or the gate stacks 435-440 may be altered as is desired and known in the art. For example, a silicide layer (not shown) may be formed between the conductive layer 415 and the second insulating layer 420. The silicide layer may be included in the transfer and reset transistor gate stacks 435-440, or in all of the transistor gate structures in an image sensor circuit, and may be titanium silicide, tungsten silicide, cobalt silicide, molybdenum silicide, or tantalum silicide. This additional conductive layer may also be a barrier layer/refractor metal, such as TiN/W or W/Nx/W, or it could be formed entirely of WNx.

As depicted in FIG. 4E, floating diffusion regions 445 (also shown as the floating diffusion region 225 in FIG. 2A) are implanted by known methods to achieve the structure shown in FIG. 4E. The floating diffusion regions 445 are formed as n-type regions adjacent the gate stacks 435 and 440. The floating diffusion region 445 is formed between the transfer transistor 220 (FIG. 2A) gate stack and the reset transistor 230 (FIG. 2A) gate stack. Any suitable n-type dopant, such as phosphorus, arsenic, or antimony, may be used.

As depicted in FIG. 4F, the charge accumulation region 450 is implanted in the P− EPI layer 405. The charge accumulation region 450 is, illustratively, a lightly doped n-type region. In another embodiment, the charge accumulation region 450 can be a heavily doped n+ region. An n-type dopant, such as phosphorus, arsenic, or antimony, may be implanted through the opening and into the P− EPI layer 405. Multiple implants may be used to tailor the profile of region 450. If desired, an angled implantation may be conducted to form the region 450, such that implantation is carried out at angles other than 90 degrees relative to the surface of the EPI layer 405. The charge accumulation region 450 can be formed simultaneously with the photosensor charge accumulation regions 210 of pixel cells 110.

Optionally, a p-type surface layer 455, analogous to the p-type surface layer 215 of the photosensor 205 of pixel cell 110 (FIG. 2A), can be implanted. The doped surface layer 455 is doped to the first conductivity type. Illustratively, doped surface layer 455 is a highly doped p+ surface layer. A p-type dopant, such as boron, indium, or any other suitable p-type dopant, may be used to form the p+ surface layer 455.

The p+ surface layer 455 may be formed by known techniques. For example, layer 455 may be formed by implanting p-type ions through openings in a layer of photoresist. Alternatively, layer 455 may be formed by a gas source plasma doping process, or by diffusing a p-type dopant into the P− EPI layer 405 from an in-situ doped layer or a doped oxide layer deposited over the area where layer 455 is to be formed.

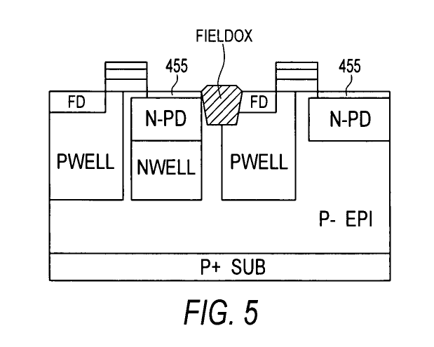

Conventional processing methods may be used to complete the N-well barrier region 425. Insulating, shielding, and metallization layers can be formed to connect gate lines, and provide connection to Vaa-pix, and other connections to the N-well barrier region 425. Further, the entire surface may be covered with a passivation layer (not shown) of, for example, silicon dioxide, BSG, PSG, or BPSG, which is CMP planarized and etched to provide contact holes, which are then metallized to provide contacts. Conventional layers of conductors and insulators may also be used to interconnect the structures and to connect the charge accumulation region 450 to Vaa-pix. Specifically, connection can be formed using any suitable conductive material, e.g. metal; and contact can be formed using any suitable conductive material. FIG. 5 illustrates an alternate example of the N-well region located only beneath the photodiode (PD).

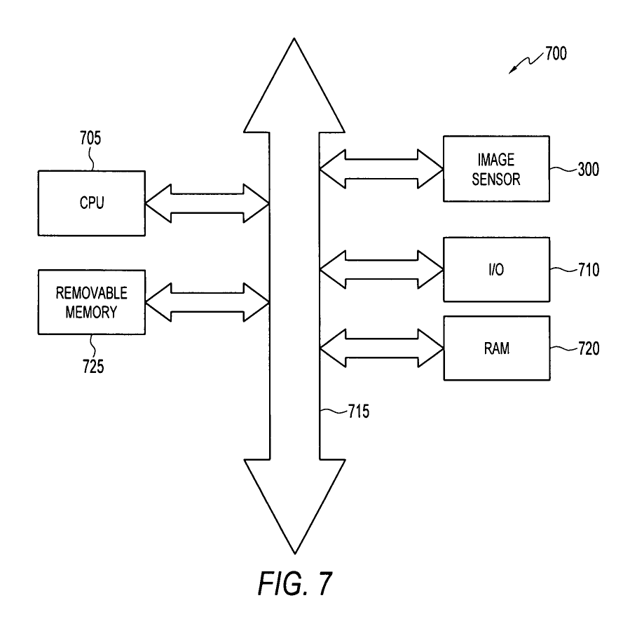

FIG. 7 illustrates a processor system 700 including an image sensor 300 of FIG. 3A. In an alternative embodiment, the system 700 can include the image sensor 315 of FIG. 3B. The system 700 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and data compression system.

The system 700, for example a camera system, generally comprises a central processing unit (CPU) 705, such as a microprocessor, that communicates with an input/output (I/O) device 710 over a bus 715. Image sensor 300 also communicates with the CPU 705 over bus 715. The processor system 700 also includes random access memory (RAM) 720, and can include removable memory 725, such as flash memory, which also communicates with CPU 705 over the bus 715. Image sensor 300 may be combined with a processor, such as a CPU, digital signal processor, or microprocessor, with or without memory storage on a single integrated circuit or on a different chip than the processor.

It is again noted that the above description and drawings are exemplary and illustrate preferred embodiments that achieve the objects, features and advantages of the present invention. It is not intended that the present invention be limited to the illustrated embodiments. Any modification of the present invention which comes within the spirit and scope of the following claims should be considered part of the present invention.

What is claimed as new and desired to be protected by Letters Patent of the United States is:

1. An image sensor comprising:
a substrate;
an array of pixel cells formed in association with the substrate wherein said array of pixel cells includes an active array region and a black region; and
at least one N-well pixel isolation region formed between the active array region and the black region.

2. The image sensor of claim 1, further comprising peripheral circuitry adjacent the array, wherein the at least one N-well pixel isolation region includes a portion located between at least one pixel cell of the black region and the peripheral circuitry.

3. The image sensor of claim 1, wherein the array comprises an active array region comprising a first portion of pixel cells, and at least one black region comprising a second portion of pixel cells not in the active array region, and wherein the at least one N-well pixel isolation region is between the active array region and the at least one black region.

4. The image sensor of claim 3, wherein the second portion of pixel cells includes a first black region adjacent to a first side of the active array region and at least a second black region adjacent to a second side of the active array region, the first and at least second black regions for determining the black level of the array, and wherein the at least one N-well pixel isolation region is located between the active array region and the first and at least second black region.

5. The image sensor of claim 3, wherein the at least one N-well pixel isolation region surrounds the active array region.

6. The image sensor of claim 3, wherein the at least one N-well pixel isolation region surrounds the at least one black region.

7. The image sensor of claim 1, further comprising a plurality of N-well pixel isolation regions.

8. The image sensor of claim 1, wherein the at least one N-well pixel isolation region is configured as at least a portion of a pixel cell in the array.

9. The image sensor of claim 8, wherein the N-well pixel isolation region is configured as a row of pixel cells in the array.

10. The image sensor of claim 8, wherein the N-well pixel isolation region is configured as a column of pixel cells in the array.

11. The image sensor of claim 1, wherein the image sensor is a CMOS image sensor.

12. An image sensor comprising:
an array of pixel cells, the array comprising an active array region including a first portion of pixel cells and at least one black region for determining the black level of the array, the at least one black region including a second portion of pixel cells not in the active array region;
peripheral circuitry adjacent to the array; and
at least one N-well pixel isolation region between the array and the peripheral circuitry and the array and the at least one black region.

13. A barrier region for isolating devices of an image sensor, the barrier region comprising:
a substrate; and
a N-well pixel isolation region.

14. The barrier region of claim 13, wherein the N-well pixel isolation region is configured as a group of pixel cells.

15. The barrier region of claim 13, wherein the N-well pixel isolation region is configured as a row of pixel cells

16. The barrier region of claim 13, wherein the N-well pixel isolation region is configured as a column of pixel cells.

17. The barrier region of claim 13, wherein the N-well pixel isolation region includes N-well implants.

18. The barrier region of claim 13, wherein the N-well pixel isolation region includes N-well stripes.

19. A processor system, comprising:
(i) a processor; and
(ii) an image sensor coupled to the processor, the image sensor comprising:
a substrate;
an array of pixel cells in association with the substrate;
at least one N-well pixel isolation region formed over the substrate adjacent at least one pixel cell.

20. The processor system of claim 19, wherein the image sensor is a CMOS image sensor.

21. The processor system of claim 19, wherein the image sensor is a CCD image sensor.

22. The processor system of claim 19, further comprising peripheral circuitry adjacent to the array, wherein the at least one N-well pixel isolation region is between the array and the peripheral circuitry.

23. The processor system of claim 19, wherein the array comprises an active array region comprising a first portion of pixel cells, and at least one black region for determining a black level for the array comprising a second portion of pixel cells not in the active array region, and wherein the at least one N-well pixel isolation region is located between the active array region and the at least one black region.

24. A method of forming a barrier region for isolating black region of an image sensor, the method comprising the acts of:
forming an active array of pixels;
forming a black region including an array of pixels; and
forming, at a location between said active array of pixels and said black region of pixels an N-well pixel isolation region.

25. The method of claim 24 wherein the act of forming the N-well pixel isolation region comprises forming the N-well pixel isolation region to be located within a portion of a pixel cell array.

26. The method of claim 24, wherein the act of forming the N-well pixel isolation region includes forming the N-well pixel isolation region as a row of pixel cells.

27. The method of claim 24, wherein the act of forming the N-well pixel isolation region comprises forming the N-well pixel isolation region as a column of pixel cells.

28. A method of forming an image sensor, the method comprising:
providing a substrate;
providing an array of pixel cells in association with the substrate wherein said array of pixel cells includes an active array region and a black region; and
forming at least one N-well pixel isolation region located between said active array region and said black region.

29. The method of claim 28, further comprising peripheral circuitry adjacent to the array, wherein a portion of the at least one N-well pixel isolation region is located between the black region and the peripheral circuitry.

30. The method of claim 28, wherein black region includes a first black region adjacent to a first side of the active array region and at least a second black region adjacent to a second side of the active array region, the first and at least second black regions for determining the black level of the array, and wherein a portion of the N-well pixel isolation region is located between the first black region and second black region and the active array region.

31. The method of claim 28, wherein the act of forming the at least one N-well pixel isolation region comprises forming the at least one N-well pixel isolation region surrounding the active array region.

32. The method of claim 28, wherein the act of forming the at least one N-well pixel isolation region comprises forming the at least one N-well pixel isolation region surrounding the black region.

33. A method of forming an image sensor, the method comprising:
providing an array of pixel cells on a substrate wherein said array includes an active array and a black region;
providing peripheral circuitry adjacent to the array of pixel cells; and
forming at least one N-well pixel isolation region located between said peripheral circuitry and said black region.

34. The method of claim 33, wherein the act of forming at least one N-well pixel isolation region includes forming a portion of the N-well pixel isolation region between the active array and the black region.
